(19) United States
(12) Patent Application Publication
(10) Pub. No.: US 2014/0116509 A1
(43) Pub. Date: May 1, 2014

(54) Solid-State Dye-Sensitized Solar Cell Using Oxidative Dopant

(71) Applicants: Sean Andrew Vail, Vancouver, WA (US); Alexey Koposov, Vancouver, WA (US); Wei Pan, Vancouver, WA (US); Gary D. Foley, Portland, OR (US); Jong-Jan Lee, Camas, WA (US)

(72) Inventors: Sean Andrew Vail, Vancouver, WA (US); Alexey Koposov, Vancouver, WA (US); Wei Pan, Vancouver, WA (US); Gary D. Foley, Portland, OR (US); Jong-Jan Lee, Camas, WA (US)

(21) Appl. No.: 13/664,256

(22) Filed: Oct. 30, 2012

(51) Int. Cl. H01L 51/00; H01B 1/12

(52) U.S. Cl. CPC H01L 51/0036; H01B 1/12
USPC 136/263; 252/519.3; 252/519.21; 252/519.33

(57) ABSTRACT

A solid-state hole transport composite material (ssHTM) is provided. The ssHTM is made from a neutral charge first p-type organic semiconductor, and a chemically oxidized first p-type semiconductor, where the dopants are silver(I) containing materials. A reduced form of the silver(I) containing material is also retained as functional component in the ssHTM. In one aspect, the silver(I) containing material is silver bis(trifluoromethanesulfonyl)imide (TFSI). In another aspect, the first p-type organic semiconductor is 2,2′,7,7′-tetrakis(N,N-di-p-methoxyphenylamine)-9,9′-spirobifluorene (Spiro-OMeTAD). In one variation, the ssHTM additionally includes a first p-type organic semiconductor doped with an ionic dopant such as lithium (Li⁺), sodium (Na⁺), potassium (K⁺), or combinations of the above-mentioned materials. Also provided are a method for synthesizing the above-described ssHTM, and a solid-state dye solar cell (ssDSC) fabricated from the ssHTM.

### RELATED APPLICATIONS

This application is a Continuation-in-part of an application entitled, SOLID-STATE DYE-SENSITIZED SOLAR CELL USING SODIUM OR POTASSIUM IONIC DOPANT, invented by Sean Vail et al., Ser. No. 13/461,674, filed May 1, 2012, Attorney Docket No. SLA3164.

### BACKGROUND OF THE INVENTION

1. Field of the Invention

This invention, generally relates to photovoltaic solar cells and, more particularly, to a solid-state hole transport composite material with an oxidative dopant.

2. Description of the Related Art

The dye-sensitized solar cell (DSC) represents both a promising and cost-effective alternative to expensive, thin-film photovoltaic technologies. In general, a conventional DSC device is composed of a porous semiconducting metal oxide, a dye (photosensitizer) that harvests incident light, and a liquid electrolyte for transport of positive charges (holes) from the photoexcited dye. Although appreciable power conversion efficiencies (PCEs) have been achieved using molecular photosensitizers in a conventional. DSC configuration, the quest for all solid-state devices has fostered the development of solid-state dye solar cells (ssDSCs) through which the liquid, electrolyte is replaced by a solid hole-transport material (HTM). Overall, ssDSCs offer both practical and technological advantages compared to conventional DSCs, for which long-term stability and large-scale deployment are hindered by potential leakage issues associated with the volatile and corrosive nature of the electrolyte.

FIG. 1 is a schematic diagram depicting electronic processes and major loss mechanisms in a solid-state dye-sensitized solar cell (prior art). The absorption of light (photosensitizer) is followed by electron injection from the photoexcited state of the dye (D*) into the TiO₂ conduction hand [1]. Subsequently, hole transfer proceeds from the oxidized dye (D⁺) to the HTM, after which holes are transported to a metallic counter electrode via charge “hopping” mechanisms along the HTM [2]. Following electron, injection from the photoexcited dye, competition in terms of “recapture” of injected electrons (from TiO₂) by the oxidized dye (recombination) may occur [3]. Finally, additional recombination events involving electrons in the TiO₂ and holes in the HTM may proceed [4]. Strategies towards high performance ssDSC devices are focused on maximizing the efficiency of processes [1] and [2] while, at the same time, minimizing the negative impact from [3] and [4].

A ssDSC device can be fabricated using metal oxide nanoparticles with attached photosensitizer as the absorber layer, see FIG. 3A. Briefly, an appropriate blocking layer is deposited on top of a transparent conducting oxide (TCO) layer to prevent ohmic contact between the HTM and TCO. Next, a metal oxide layer (in the form of nanoparticles, nanotubes, nanowires, etc., for example) is deposited on top of the blocking layer. Subsequent to deposition, the metal oxide substrate is treated with a photosensitizer to afford a monolayer of absorber material along the surface of the metal oxide. Next, an HTM is applied to the metal oxide/photosensitizer. Finally, a metal layer (Ag or Au) is deposited on top of the HTM to complete the device.

FIG. 2 is a diagram depicting the molecular structure of 2,2′,7,7′-tetrakis(N,N-di-p-methoxyphenylamine)-9,9′-spirobifluorene (Spiro-OMeTAD) (prior art). Perhaps the most challenging aspect of ssDSC development is the preparation and optimization of the HTM matrix formulation and deposition processes, while the fabrication of the metal oxide substrate and photosensitization strategies can be directly transferred from the current DSC technology. Although 2,2′7,7′-tetrakis(N,N-di-p-methoxyphenylamine)-9,9′-spirobifluorene (Spiro-OMeTAD) has been the preferred solid-state hole transport material (ssHTM) for ssDSC, the development of suitable alternatives represent active areas of interest.

Overall, the low intrinsic conductivity of pristine Spiro-OMeTAD films imposes challenges towards the realization of highly efficient ssDSCs. In general, the low conductivity for organic HTMs (versus inorganic) may be rationalized, at least in part, by higher degrees of disorder which afford a broad distribution of traps states throughout the HTM network. In order to compensate for the low conductivity of pure Spiro-OMeTAD films, a lithium ion (Li⁺) source [such as lithium bis(trifluoromethylsulfonyl)imide or LiTFSI, for example] is routinely incorporated into the HTM formulation. The necessity for the presence of Li⁺ in the Spiro-OMeTAD matrix was initially demonstrated by Bach et al., for which an ssDSC containing “lithium-doped” Spiro-OMeTAD demonstrated an overall efficiency of 0.74% (with accessory dopant) versus 0.04% for a control device (no additives).¹

Since this pioneering work, subsequent publications have verified the critical role of Li⁺ in ssDSCs based upon Spiro-OMeTAD towards achieving higher PCEs. Krüger et al. demonstrated an ssDSC efficiency of 2.56% using Spiro-OMeTAD containing LiTFSI and 4-tert-butyl pyridine (TBP), whereby an appreciable open-circuit voltage (V_{oc}) from suppression of interfacial charge carrier recombination was confirmed by nanosecond laser spectroscopy.² Snaith et al. showed that the addition of a redox inactive ionic dopant (Li⁺ in the form of LiTFSI) afforded up to a 100-fold increase in conductivity and up to one order of magnitude enhancement in hole mobility for the Spiro-OMeTAD composite.³ Studies reported both previously and subsequently to the aforementioned support the notion that appropriate doping with Li⁺ is critical for achieving high efficiencies in ssDSCs using Spiro-OMeTAD as HTM.^{4, 5}

Although a detailed treatment of the underlying mechanism(s) through which the observed enhancements are realized is not explicitly presented herein, it appears likely that Li⁺ does not provide access to higher oxidation states of Spiro-OMeTAD. In addition, it is possible that the localized (positive) charges populated along the TiO₂ surface may facilitate electron injection from the attached photosensitizer following irradiation as well as provide conductive channels throughout the HTM network. However, the fact that it has been shown internally that increased Li⁺ concentrations in the Spiro-OMeTAD matrix negatively impacts the V_{oc} of the device when used in combination with a high molar extinction coefficient photosensitizer suggests that Li⁺ influences the position of the TiO₂ Fermi level, whereby increased short-circuit photocurrent density (J_{sc}) is enhanced at the expense of open circuit voltage (V_{oc}).

To further compensate for the poor conductivity of pristine Spiro-OMeTAD films, the generation of additional charge carriers via chemical doping methods has been employed. Through appropriate strategies, the conductivity through the HTM matrix can be increased, thereby decreasing the frequency for recombination events that negatively impact V_{oc}. A large variety of materials have been described for p-doping applications including strongly electron-accepting organic materials, (tetrafluorotetracyanoquinodimethane, F4-TCNQ),⁶ transition metal oxides (tungsten oxide, WO₃),⁷ metal organic complexes (molybdenum (tris[1,2-bis(trifluoromethyl)ethane-1,2-dithiolene], Mo(tfd)₃),⁸ and redox active salts.^{9, 10} Unfortunately, for many approaches the materials are applied by vacuum deposition techniques, exhibit impractically low solubility in organic solvents and/or are either generally unstable or too highly reactive and therefore prone to undesirable side reactions.

With respect to ssDSC, solution-based deposition in combination with an organic HTM would prove most favorable which, at the same time, requires chemical inertness towards the HTM, TiO₂-anchored photosensitizer and metal oxide semiconductor. For ssDSC, Bach et al. employed tris(p-bromophenyl)ammoniumyl hexachloroantimonate [N(p-C₆H₄Br)₃SbCl₆] as dopant in ssDSC with Spiro-OMeTAD as HTM.¹ Recently, Grätzel et al. described the incorporation of a tris[2-(1H-pyrazol-1-yl)pyridine] cobalt(III) complex (designated FK102) as dopant in ssDSC with an organic dye as photosensitizer (designated Y123) and Spiro-OMeTAD as HTM.¹¹ Overall, FK102 was determined to have a redox potential of ˜1.06 V (NHE), thereby providing approximately 350 mV driving force for the one electron oxidation of Spiro-OMeTAD. In spite of these successes, the extent (or scope) to which p-doping in ssDSC is beneficial remains unresolved since the increase in conductivity (due to increased population of charge carriers due to dopant) is often counterbalanced by an increase in charge recombination.

1. Bach, U.; Lupo, D.; Comte, P.; Moser, J.; Weissörtel, F.; Salbeck, J.; Spreitzer, H.; Gräzel, M. Nature 1998, 39,5, 583-585.

2. Krüger, J.; Plass, R.; Cevey, L.; Piccirelli, M.; Grätzel, M.; Bach, U. Applied Physics Letters 2001, 79, 2085-2087.

3. Snaith, H. J.; Gräzel, M. Applied Physics Letters 2006, 89, 262114-1-262114-3.

4. Hague, S. A.; Tachibana, Y.; Willis, R. L.; Moser, J. E.; Grätzel, M.; King, D. R.; Durrant, J. R. Journal of Physical Chemistry B 2000, 104, 538-547.

5. Fabreget-Santiago, F.; Bisquert, J.; Chevey, L.; Chen, P.; Wang, M.; Zakeerudiin, S. M.; Grätzel, M. Journal of the American Chemical Society 2009, 131, 558-562.

6. Gao, W.; Khan, A. Journal of Applied Physics 2003, 94, 359-366.

7. Meyer, J.; Hamwi, S.; Schmale, S.; Winkler, T.; Johannes, H.-H.; Riedl, T.; Kowalsky, W. Journal of Materials Chemistry 2009, 19, 702-705.

8. Qi, Y.; Sajoto, T.; Barlow, S.; Kim, E.-G.; Marder, S. R.; Khan, A. Journal of the American Chemical Society 2009, 131, 12530-12531.

9. EPI 289 030; 2003.

10. U.S. Pat. No. 7,061,009; 2006.

11. Burschka, J.; Dualeh, A.; Kessler, F.; Baranoff, E.; Cevey-Ha, N-L.; Yi, C.; Nazeeruddin, M. K.; Grätzel, M. Journal of the American Chemical Society 2011, 133, 18042-18045.

It would be advantageous if organic p-type (hole transport) materials such as Spiro-OMeTAD could be appropriately doped to improve photovoltaic performance with respect to short-circuit current density (J_{sc}), open circuit voltage (V_{oc}), fill factor (FF), and/or series resistance (Rₛ), towards achieving higher overall PCEs.

### SUMMARY OF THE INVENTION

Described herein is a strategy for effective in situ doping of hole-transport material (HTM) matrices for improved ssDSC performance. As a proof of concept, a silver(I) salt (silver bis(trifluoromethanesulfonyl)imide or AgTFSI) is employed in combination with Spiro-OMeTAD as representative HTM. Optical measurements confirmed the successful and efficient one-electron oxidation of Spiro-OMeTAD. Furthermore, prototype ssDSC devices demonstrate significant performance enhancements relative to control devices (without AgTFSI). These observations are attributed, at least in part, to the suppression of recombination events arising directly from an increase in HTM conductivity due to appropriate chemical (oxidative) doping. Finally, although many aspects of the ssDSC prototype development conform to conventional processing strategies, there currently exist very few successful demonstrations of a significantly beneficial impact of chemical doping of HTM in ssDSC.

Accordingly, a solid-state hole transport composite material (ssHTM) is provided. The ssHTM is made from a neutral charge first p.-type organic semiconductor, and a chemically oxidized first p-type semiconductor, where the dopants are silver(I) containing materials. A reduced form of the silver(I) containing material is also retained as a functional component in the ssHTM. In one aspect, the silver(I) containing material is silver bis(trifluoromethanesulfonyl)imide (TFSI). In another aspect, the first p-type organic semiconductor is 2,2′,7,7′-tetrakis(N,N-di-p-methoxyphenylamine)-9,9′-spirobifluorene (Spiro-OMeTAD). In one variation, the ssHTM in addition to above-mentioned materials, includes a first p-type organic semiconductor doped with an ionic dopant such as lithium (Li⁺), sodium (Na⁺), potassium (K⁺), or combinations of the above-mentioned materials.

Also provided is a method for synthesizing a ssHTM. The method mixes a first p-type organic semiconductor with a silver(I) containing material in a single step. The method at least partially chemically oxidizes the first p-type organic semiconductor, creating as a result, a ssHTM formed from a neutral charge first p-type organic semiconductor, a chemically oxidized first p-type organic semiconductor, and a reduced form of the silver(I) containing material, retained as a functional component in the ssHTM.

In addition, a solid-state dye solar cell (ssDSC) is provided with a ssHTM. The ssDSC is formed from a transparent platform, and a transparent conducting oxide (TCO) overlying the transparent platform. A sensitized n-type semiconductor overlies the TCO, and a ssHTM, as described above, overlies the sensitized n-type semiconductor. Finally, a metal layer overlies the ssHTM.

Additional details of the above-described ssHTM, ssHTM synthesis method, and ssDSC, are provided below.

### BRIEF DESCRIPTION OF THE DRAWINGS

FIG. 1 is a schematic diagram depicting electronic processes and major loss mechanisms in a solid-state dye-sensitized solar cell (prior art).

FIG. 2 is a diagram depicting the molecular structure of 2,2′,7,7′-tetrakis(N,N-di-p-methoxyphenylamine)-9,9′-spirobifluorene (Spiro-OMeTAD) (prior art).

FIGS. 3A and 3B are partial cross-sectional views of a solid-state dye solar cell (ssDSC) with a solid-state hole transport material (ssHTM).

FIG. 4 is a diagram depicting the chemical structure of silver bis(trifluoromethanesulfonyl)imide (AgTFSI).

FIG. 5 is a graph depicting the optical absorbance spectra of Spiro-OMeTAD (solid line) and Spiro-OMeTAD doped with AgTFSI at 1 mol % (dash line) in CB/CH₃CN from 400-900 nm.

FIG. 6 is a graph depicting EQE spectra for ssDSCs containing Spiro-OMeTAD (SU1402, control) and Spiro-OMeTAD doped with AgTFSI at 1.4 mol % (SU1605), 3.5 mol % (SU1606), 7.5 mol % (SU1608) or 15.1 mol % (SU1607) from 300-800 nm.

FIG. 7 is a graph of IV curves for ssDSCs containing Spiro-OMeTAD (SU1402, control) and Spiro-OMeTAD doped with AgTFSI at 1.4 mol % (SU1605), 3.5 mol % (SU1606), 7.5 mol % (SU1608) or 15.1 mol % (SU1607).

FIG. 8 is a flowchart illustrating a method for synthesizing a ssHTM.

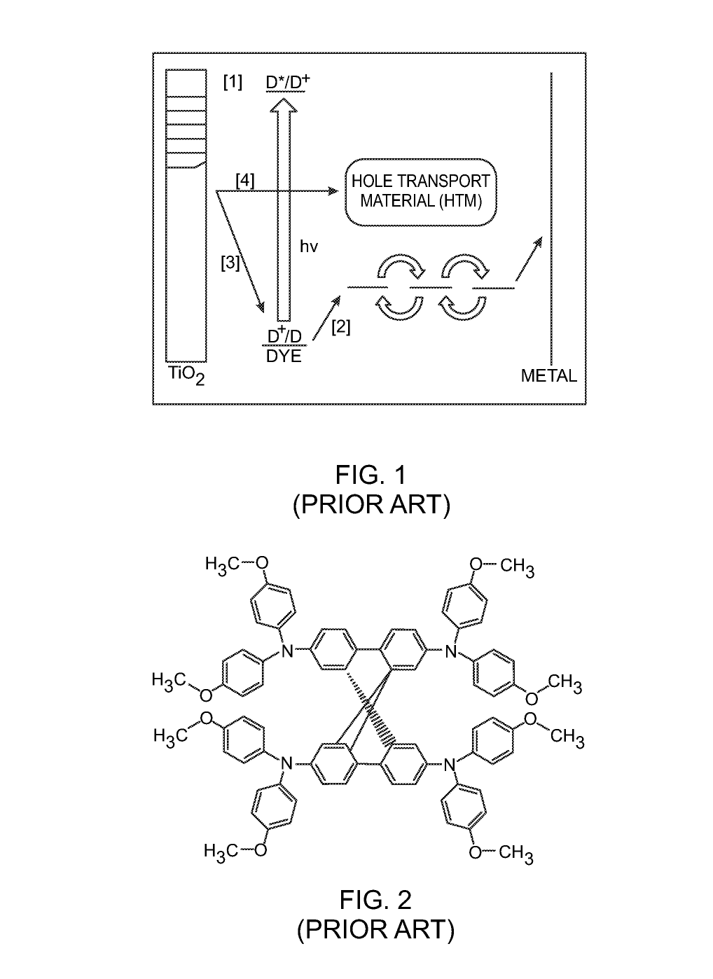

### DETAILED DESCRIPTION

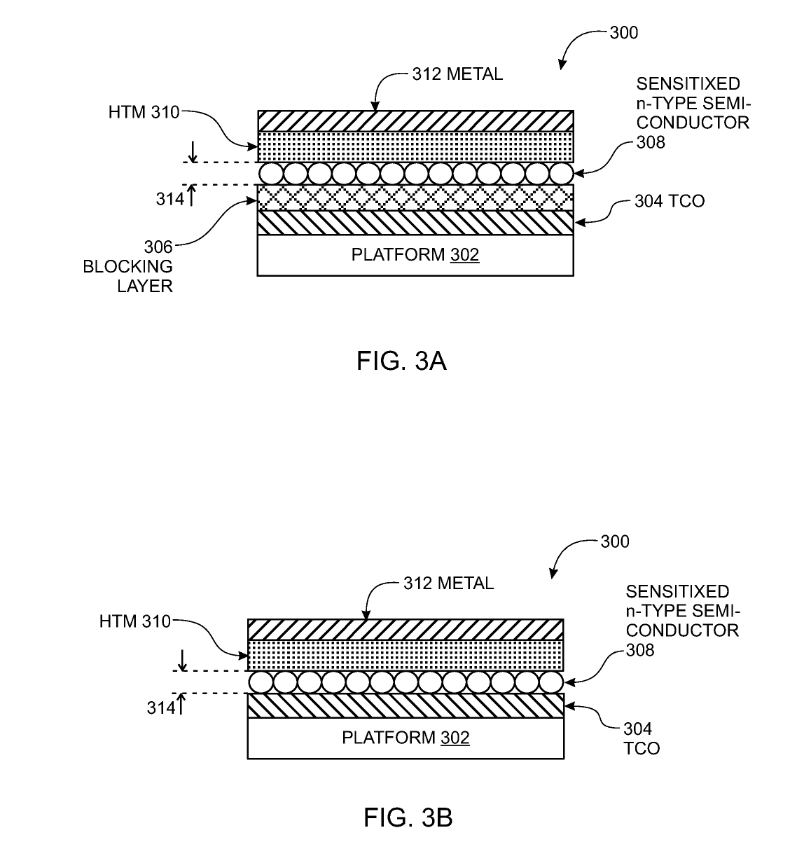

FIGS. 3A and 3B are partial cross-sectional views of a solid-state dye solar cell (ssDSC) with a solid-state hole transport material (ssHTM). The ssDSC 300 comprises a transparent platform 302, typically made from glass or flexible material. A transparent conducting oxide (TCO) 304 overlies the transparent platform 302. Examples of TCO materials include fluorine doped tin oxide (FTO), and indium tin oxide (ITO). As shown in FIG. 3A, a blocking layer 306 overlies the TCO 304. The blocking layer 306 is electrically conductive, but prevents ohmic contact between the TCO and an ssHTM layer. A sensitized n-type semiconductor 308 overlies the blocking layer 306. The ssHTM layer 310 overlies the sensitized n-type semiconductor 308. A metal layer 312 overlies the ssHTM 310. For example, the metal may be Ag or Au. Alternatively, FIG. 3B depicts an ssDSC with no blocking layer.

The ssHTM 310 comprises a neutral charge first p-type organic semiconductor, a chemically oxidized first p-type organic semiconductor, with silver(I) containing material dopants, and a reduced form of the silver(I) containing material, retained as a functional component in the ssHTM 310. As used herein, “function component” implies a beneficial impact on HTM performance arising from the inclusion of the reduced form of the silver(I) containing material. That is, the “functional” aspect is an enhancement of the intrinsic properties of the HTM composite. Most likely, the enhancement manifests itself in the form of improved conductivity, and/or improved hole mobility for the HTM (or HTM composite).

It should be understood that when a certain amount of Ag(I) material is added to the HTM, a partial oxidation of HTM (to HTM+) occurs, which is correlated directly with the amount of oxidative dopant [Ag(I) material] added. However, it is likely that HTM oxidation by Ag(I) proceeds with less than 100% efficiency and, therefore, no quantitative conversion of Ag(I) occurs, to a reduced form via HTM oxidation in other words, it is likely that a residual amount of Ag(I) dopant materials added to HTM is unchanged in the composite, and stays intact as Ag(I) material in the composite. Therefore, the ssHTM may include a residual amount of silver(I) containing material that has not oxidized the HTM and thus has not been reduced to a reduced form of the silver(I) material. However, in some aspects, there may be no residual amount of Ag(I) containing material in the ssHTM that has not oxidized the ssHTM.

The silver(I) containing material is preferably silver bis(trifluoromethanesulfonyl)imide (TFSI), but may alternatively be one of the following materials: silver(I) containing materials including silver acetate, silver acetoacetate, silver acetylacetonate, silver bromide, silver carbonate, silver chloride, silver fluoride, silver hexafluoroarsenate, silver hexafluorophosphate, silver iodide, silver nitrate, silver phosphate, silver sulfate, silver tetrafluoroborate, silver trifluoroacetate, silver trifluoromethanesulfonate, silver salts of organic carboxylic acids (carboxylate salts), silver salts of organic phosphonic acids (phosphonate salts), silver salts of organic sulfonic acids (sulfonate salts), silver salts of bis(alkylsulfonyl)imides, silver salts of bis(trifluoroalkylsulfonyl)imides, silver(I) molecular complexes, or combinations of the above-mentioned materials. Other, unmentioned, silver(I) containing materials may possibly be employed.

Typically, the blocking layer 306 consists of a thin layer of compact metal oxide. For example, the blocking layer may be a compact film of TiO₂, which is deposited by spray pyrolysis from a TiO₂ precursor. Although the compact layer is conductive, it forms a physical barrier to prevent HTM from contacting the TCO (ohmic). Deposition of the HTM solution might otherwise lead to penetration through the n-type semiconductor 308 (e.g. nanoparticle TiO₂) to the underlying TCO surface.

The junction formed between the p-type semiconductor material (hole transporter) 310 and the n-type semiconductor material (electron transporter) 308 constitutes a p-n heterojunction, which represents the fundamental basis of diodes and transistors including related devices such as light emitting diodes (LEDs) and photovoltaic (PV) cells. “Solid-state” simply implies that the material is a solid or quasi-solid (non-liquid) under ambient conditions.

The n-type semiconductor 308 sensitizer may consist of molecular (organic) materials, metal-organic complexes, ruthenium-pyridyl complexes, porphyrins, metalloporphyrins, phthalocyanines, metallophthalocyanines, squaraines, indolenes, coumarins, thiophene and fluorene-based materials, monomeric oligomeric, polymeric photosensitizers, quantum dots, inorganic materials, organic-inorganic materials, and combinations of the above-mentioned materials. However, this is not an exhaustive list. Briefly, a quantum dot is a semiconductor whose electronic characteristics are closely related to the size and shape of the individual crystal. Consequently, such materials have electronic properties intermediate between those of bulk semiconductors and those of discrete molecules.

The n-type semiconductor is typically one of the following: titanium (TiO₂), aluminum (Al₂O₃), tin (SnO₂), magnesium (MgO), tungsten (WO₃), niobium (Nb₂O₅), zinc oxide (ZnO), combinations of the above-mentioned oxides, and doped variations of the above-mentioned oxides. Other, unmentioned, materials may possibly be employed as the n-type semiconductor.

The n-type semiconductor 308 may take the form of nanoparticles, nanotubes, nanorods, nanowires, or combinations of the above-mentioned morphologies. Morphology is specific to the n-type semiconductor. The ssDSC may also be enabled with other morphologies. The sensitized n-type semiconductor has a thickness 314 in the range of 0.1 to 20 microns. Thickness 314 applies to the n-type semiconductor (metal oxide). It should be understood that this is not intended to be an exhaustive list of n-type semiconductor materials or forms.

The first p-type organic semiconductor may be molecular (collection of discrete molecules, chemically identical or different), oligomeric, polymeric materials, or combinations thereof. In one aspect, the first p-type organic semiconductor is 2,2′,7,7′-tetrakis(N,N-di-p-methoxyphenylamine)-9,9′-spirobifluorene (Spiro-OMeTAD). The structure of the first p-type organic semiconductor may be amorphous, crystalline, semi-crystalline, or combinations thereof. However, the first p-type semiconductor is not limited to any particular type of structure. The percentage of chemically oxidized first p-type organic semiconductor to neutral charge first p-type organic semiconductor is typically in the range of 0.1 to 25%. In one aspect, the ssHTM 310 further comprises a first p-type organic semiconductor doped with an ionic dopant such as lithium (Li⁺), sodium (Na⁺), potassium (K⁺).

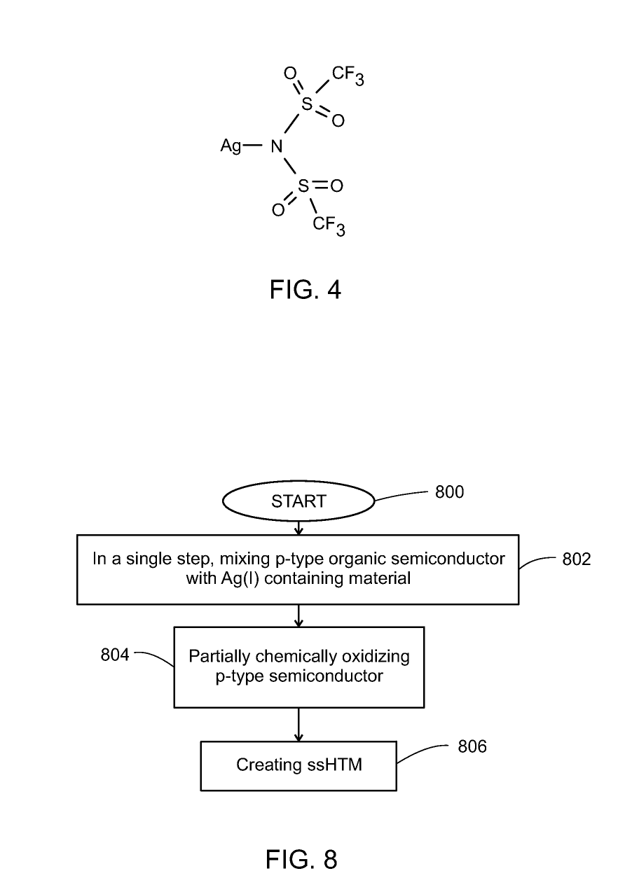

FIG. 4 is a diagram depicting the chemical structure of silver bis(trifluoromethanesulfonyl)imide (AgTFSI). Silver(I) salts can function as powerful oxidizing agents in the appropriate medium, although their relative oxidizing ability is variable and highly dependent on the nature of the environment (solvent). In order to test the practical application of Ag(I) salts as p-type dopants for Spiro-OMeTAD in ssDSC, a set of optical experiments was performed using AgTFSI. In particular, AgTFSI was judiciously chosen over analogous silver(I) salts due to an appreciable solubility in organic solvents, as well as the fact that the TFSI counterion is common to that of the lithium source (LiTFSI) in conventional Spiro-OMeTAD formulations. Furthermore, it is plausible that high degrees of charge delocalization associated with the large TFSI ion may either induce preferential stacking of HTMs or simply function as “bridges” across trap sites, thereby improving overall conductivity through the HTM network.

### Spiro-OMeTAD Oxidation by AgTFSI Studied by Optical Methods:

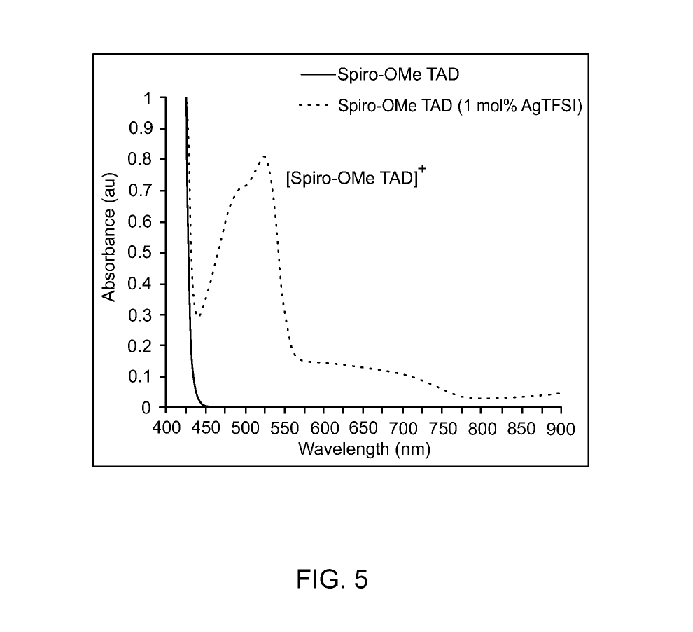

FIG. 5 is a graph depicting the optical absorbance spectra of Spiro-OMeTAD (solid line) and Spiro-OMeTAD doped with AgTFSI at 1 mol % (dash line) in CB/CH₃CN from 400-900 nm. The y-axis: Absorbance in arbitrary units (au); the x-axis: Wavelength in nanometers (nm). For the optical experiments, a solution of Spiro-OMeTAD in chlorobenzene (CB) was utilized. From this stock solution, subsequent dilutions with chlorobenzene and doping with aliquots of AgTFSI dissolved in acetonitrile (CH₃CN) were performed to afford 1, 5 and 10 mol % doping levels (relative to Spiro-OMeTAD). The optical absorption spectra for solutions of Spiro-OMeTAD [pristine (undoped) and doped with 1 mol % AgTFSI] dissolved in chlorobenzene at equimolar concentrations are presented in the figure.

As can be seen from FIG. 5, Spiro-OMeTAD exhibits strong absorption features at wavelengths less than 450 nanometers (nm). As previously mentioned, addition of Li⁺ ions does not promote oxidation of the Spiro-OMeTAD molecule so that the spectra of Spiro-OMeTAD in the presence or absence of LiTFSI remains unchanged. In contrast, the Spiro-OMeTAD solution doped with AgTFSI (1 mol %) exhibits a new absorption peak (λₘₐₓ˜525 nm). Based upon the spectral features, this peak is unambiguously assigned to the successful oxidation of Spiro-OMeTAD to Spiro-OMeTAD⁺.

Prototype ssDSCs Containing AgTFSI (1.4% to 15.1 mol % Doping Based on Spiro-OMeTAD): Formulations

For the prototype ssDSCs, an organic photosensitizer was employed as the absorber material. In general, HTM formulations consisting of Spiro-OMeTAD, 4-tert-butyl pyridine (TBP), AgTFSI and LiTFSI (where indicated) in a mixture of chlorobenzene (CB) and acetonitrile (CH₃CN) were spin-coated onto TiO₂ nanoparticle substrates that had previously been soaked in a solution of photosensitizer (0.1 mM) dissolved in a mixture of tert-butanol and CH₃CN (1:1 by volume). Following drying, a silver electrode (200 nm thick) was deposited on top of the HTM film. The specific experimental details for the formulations are described in the following section. The evaluation of ssDSC prototype performance is comprehensively discussed in subsequent sections.

Spiro-OMeTAD/CB: Spiro-OMeTAD was dissolved in CB at 70° C. on a hot plate. Separate solutions were prepared for control and experimental formulations, as follows:
LiTFSI/CH₃CN: Lithium bis(trifluoromethylsulfonyl)imide (LiTFSI) was dissolved separately in CH₂CN.
AgTFSI/CH₃CN: Silver bis(trifluoromethanesulfonyl)imide (AgTFSI) was dissolved separately in CH₃CN.
Control Formulation(Device SU1402): To Spiro-OMeTAD/CB was added tert-butylpyridine (TBP) and LiTFSI/CH₃CN (to afford 15.1 mol % LiTFSI relative to Spiro-OMeTAD). Additional CH₃CN was added to maintain a consistent volume with experimental formulations.

Experimental Formulation 1 (Devices SU1605, 1606 and 1608): To Spiro-OMeTAD/CB was added TBP, LiTFSI/CH₃CN (to afford 15.1 mol % LiTFSI based upon Spiro-OMeTAD) and AgTFSI/CH₃CN (to afford 1.4 mol %, 1.5 mol % and 7.5 mol % AgTFSI doping level based upon Spiro-OMeTAD, respectively).

Experimental Formulation 2 (Device SU1607): To Spiro-OMeTAD/CB was added TBP and AgTFSI/CH₃CN (to afford 15.1 mol % AgTFSI doping level based upon Spiro-OMeTAD).

ssDSC Prototype Evaluation: External Quantum Efficiency (EQE %)

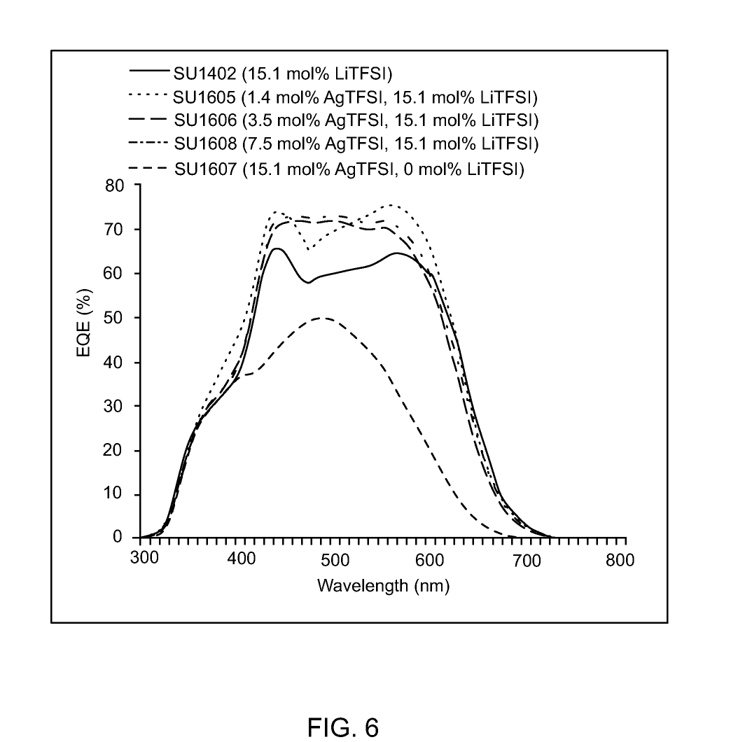

FIG. 6 is a graph depicting EQE spectra for ssDSCs containing Spiro-OMeTAD (SU1402, control) and Spiro-OMeTAD doped with AgTFSI at 1.4 mol % (SU1605), 3.5 mol % (SU1606), 7.5 mol % (SU1608) or 15.1 mol % (SU1607) from 300-800 nm. All Spiro-OMeTAD formulations contain equivalent quantities of 4-tert-butylpyridine (TBP). Furthermore, all Spiro-OMeTAD formulations contain LiTFSI (15.1 mol % based upon Spiro-OMeTAD) except for SU1607 (0 mol % LiTFSI). The y-axis: external quantum efficiency (EQE) in %; the x-axis: Wavelength in nanometers (nm). The external quantum efficiency (EQE %, 300-800 nm) for ssDSC devices SU1402 and SU1605-1608 are plotted together in the figure. In general, there exists a trend towards higher EQE % with devices containing various amounts of AgTFSI as a dopant in the Spiro-OMeTAD HTM formulation (relative to the control with no AgTFSI, with ratios of all other components in the formulation being identical). The exception is device SU1607 (15.1 mol % AgTFSI, no LiTFSI), which shows the lowest performance based upon NE measurements.

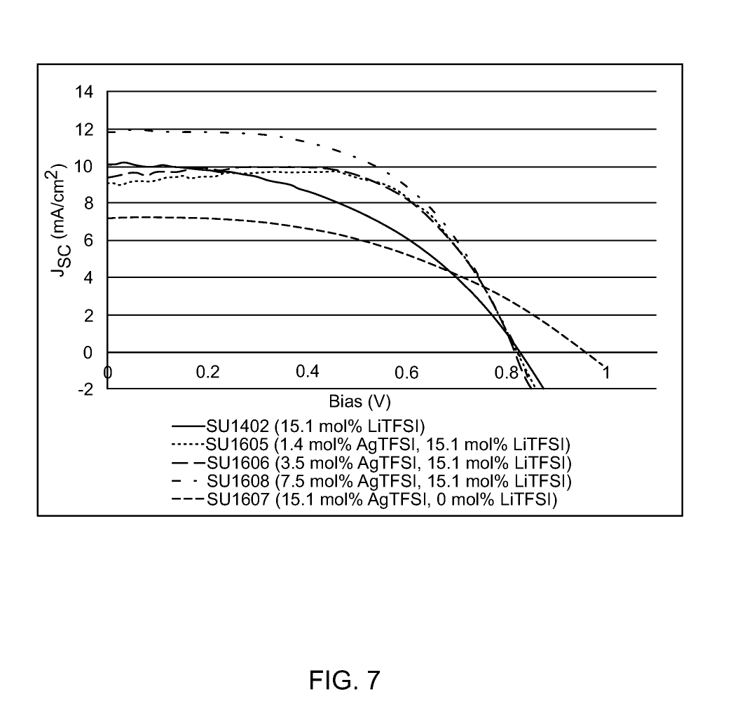

FIG. 7 is a graph of IV curves for ssDSCs containing Spiro-OMeTAD (SU1402, control) and Spiro-OMeTAD doped with AgTFSI at 1.4 mol % (SU1605), 3.5 mol % (SU1606), 7.5 mol % (SU1608) or 15.1 mol % (SU1607). All Spiro-OMeTAD formulations contain equivalent quantities of 4-tert-butylpyridine (TBP). Furthermore, all Spiro-OMeTAD formulations contain LiTFSI (15.1 mol % based upon Spiro-OMeTAD) except for SU1607 (0 mol % LiTFSI). The y-axis: J_{sc}(mA/cm²); the x-axis: voltage (V).

Table 1 is a summary of photovoltaic performance for the ssDSC devices from the I-V curves of FIG. 7, listing the following parameters: doping level of AgTFSI and LiTFSI (mol %), short-circuit current density (J_{sc}), open-circuit voltage (V_{oc}), fill factor (FF), efficiency (η), and series resistance (Rₛ).

TABLE 1

| | | | | | | | Rₛ^{b} |
|---|---|---|---|---|---|---|---|
| Device | AgTFSI^{a} | LiTFSI^{a} | J_{sc}^{b} | V_{oc}^{b} | | η^{b} | (ohm- |
| ID | (mol %) | (mol %) | (mA/cm²) | (mV) | FF^{b} | (%) | cm²) |
| SU1402 | 0 | 15.1 | 10 | 820 | 45.9 | 3.8 | 24.2 |
| SU1605 | 1.4 | 15.1 | 9.8 | 820 | 66.1 | 5.3 | 15.8 |
| SU1606 | 3.5 | 15.1 | 9.4 | 820 | 65.0 | 5.0 | 17.3 |
| SU1608 | 7.5 | 15.1 | 11.9 | 820 | 55.6 | 5.4 | 15.6 |
| SU1607 | 15.1 | 0 | 7.2 | 960 | 45.6 | 3.2 | 47.0 |

^{a}mol % based on Spiro-OMeTAD
^{b}aperture size = 0.25 cm²

As can be seen from Table 1, higher ssDSC efficiencies are obtained for devices containing HTM doped with AgTFSI (SU1605, SU1606 and SU1608) relative to the control device (SU1402), all of which contain equivalent LiTFSI content (15.1 mol % relative to HTM). Interestingly, the lowest efficiency (3.2%) yet highest V_{oc} (960 mV) is demonstrated by SU1607 (containing 15.1 mol % AgTFSI and 0 mol % Li).

FIG. 8 is a flowchart illustrating a method for synthesizing a ssHTM. The method begins with Step 800. In a single step, Step 802 mixes a first p-type organic semiconductor with a silver(I) containing material. Step 804 at least partially chemically oxidizes a portion of the first p-type organic semiconductor. As a result, Step 806 creates a ssHTM comprising a neutral charge first p-type organic semiconductor, a chemically oxidized first p-type organic semiconductor, and a reduced form of the silver(I) containing material, retained as a functional component in the ssHTM.

As noted above, it is possible that HTM oxidation by the Ag(I) proceeds with less than 100% efficiency, so it is possible that a residual amount of Ag(I) dopant materials added to HTM is unchanged in the composite, and stays intact as Ag(I) material in the composite. However, in some aspects, there may be no residual amount of Ag containing material in the ssHTM that has not oxidized the ssHTM.

In one aspect, the silver(I) containing materials of Step 802 may include silver acetate, silver acetoacetate, silver acetylacetonate, silver bromide, silver carbonate, silver chloride, silver fluoride, silver hexafluoroarsenate, silver hexafluorophosphate, silver iodide, silver nitrate, silver phosphate, silver sulfate, silver tetrafluoroborate, silver trifluoroacetate, silver trifluoromethanesulfonate, silver salts of organic carboxylic acids (carboxylate salts), silver salts of organic phosphonic acids (phosphonate salts), silver salts of organic sulfonic acids (sulfonate salts), silver salts of bis(alkylsulfonyl)imides, silver salts of bis(trifluoroalkylsulfonyl)imides, silver(I) molecular complexes, or combinations of the above-mentioned materials. Preferably, the silver(I) containing material is silver bis(trifluoromethanesulfonyl)imide (AgTFSI).

In another aspect, the first p-type organic semiconductor is molecular (collection of discrete molecules, chemically identical or different), oligomeric, polymeric materials, or combinations thereof. Preferably, the first p-type organic semiconductor is 2,2′,7,7′-tetrakis(N,N-di-p-methoxyphenylamine)-9,9′-spirobifluorene (Spiro-OMeTAD). The first p-type organic semiconductor may have a structure that is amorphous, crystalline, semi-crystalline, or combinations thereof.

In one aspect, mixing the first p-type organic semiconductor with the silver(I) containing material in Step 802 additionally includes mixing with an ionic dopant such as lithium (Li+), sodium (Na⁺), or potassium (K⁺). Then, the ssHTM of Step 806 additionally comprises a first p-type organic semiconductor doped with the ionic dopant.

A ssDSC and a ssHTM, synthesized from oxidative dopants, have been provided. Examples of particular materials have been presented to illustrate the invention. However, the invention is not limited to merely these examples. Other variations and embodiments of the invention will occur to those skilled in the art.

We claim:

1. A solid-state hole transport composite material (ssHTM) comprising:
a neutral charge first p-type organic semiconductor;
a chemically oxidized first p-type semiconductor, where the dopants are silver(I) containing materials; and,
a reduced form of the silver(I) containing material, retained as a functional component in the ssHTM.

2. The ssHTM of claim 1 wherein the silver(I) containing materials are selected from a group consisting of silver acetate, silver acetoacetate, silver acetylacetonate, silver bromide, silver carbonate, silver chloride, silver fluoride, silver hexafluoroarsenate, silver hexafluorophosphate, silver iodide, silver nitrate, silver phosphate, silver sulfate, silver tetrafluoroborate, silver trifluoroacetate, silver trifluoromethanesulfonate, silver salts of organic carboxylic acids (carboxylate salts), silver salts of organic phosphonic acids (phosphonate salts), silver salts of organic sulfonic acids (sulfonate salts), silver salts of bis(alkylsulfonyl)imides, silver salts of bis(trifluoroalkylsulfonyl)imides, silver(I) molecular complexes, and combinations of the above-mentioned materials.

3. The ssHTM of claim 1 wherein the silver(I) containing material is silver bis(trifluoromethanesulfonyl)imide (AgTFSI).

4. The ssHTM of claim 1 wherein the first p-type organic semiconductor is selected from a group consisting of molecular (collection of discrete molecules, chemically identical or different), oligomeric, polymeric materials, and combinations thereof.

5. The ssHTM of claim 1 wherein the first p-type organic semiconductor is 2,2′,7,7′-tetrakis(N,N-di-p-methoxyphenylamine)-9,9′-spirobifluorene (Spiro-OMeTAD).

6. The ssHTM of claim 1 wherein the first p-type organic semiconductor has a structure selected from a group consisting of amorphous, crystalline, semi-crystalline, and combinations thereof.

7. The ssHTM of claim 1 further comprising:
a first p-type organic semiconductor doped with an ionic dopant selected from a group consisting of lithium (Li⁺), sodium (Na⁺), potassium (K⁺), and combinations of the above-mentioned materials.

8. A method for synthesizing a solid-state hole transport composite material (ssHTM), the method comprising:
in a single step, mixing a first p-type organic semiconductor with a silver(I) containing material;
at least partially chemically oxidizing a portion of the first p-type organic semiconductor:
as a result, creating a ssHTM comprising:
a neutral charge first p-type organic semiconductor;
a chemically oxidized first p-type organic semiconductor, and,
a reduced form of the silver(I) containing material, retained as a functional component in the ssHTM.

9. The method of claim 8 wherein the silver(I) containing materials are selected from a group consisting of silver acetate, silver acetoacetate, silver acetylacetonate, silver bromide, silver carbonate, silver chloride, silver fluoride, silver hexafluoroarsenate, silver hexafluorophosphate, silver iodide, silver nitrate, silver phosphate, silver sulfate, silver tetrafluoroborate, silver trifluoroacetate, silver trifluoromethanesulfonate, silver salts of organic carboxylic acids (carboxylate salts), silver salts of organic phosphonic acids (phosphonate salts), silver salts of organic sulfonic acids (sulfonate salts), silver salts of bis(alkylsulfonyl)imides, silver salts of bis(trifluoroalkylsulfonyl)imides, silver(I) molecular complexes, and combinations of the above-mentioned materials.

10. The method of claim 8 wherein the silver(I) containing material is silver bis(trifluoromethanesulfonyl)imide (AgTFSI).

11. The method of claim 8 wherein the first p-type organic semiconductor is selected from a group consisting of molecular (collection of discrete molecules, chemically identical or different), oligomeric, polymeric materials, and combinations thereof.

12. The method of claim 8 wherein the first p-type organic semiconductor is 2,2′,7,7′-tetrakis(N,N-di-p-methoxyphenylamine)-9,9′-spirobifluorene (Spiro-OMeTAD).

13. The method of claim 8 wherein the first p-type organic semiconductor has a structure selected from a group consisting of amorphous, crystalline, semi-crystalline, and combinations thereof.

14. The method of claim 8 wherein mixing the first p-type organic semiconductor with the silver(I) containing material additionally includes mixing with an ionic dopant selected from a group consisting of lithium (Li+), sodium (Na⁺), and potassium (K⁺); and,
wherein the ssHTM additionally comprises a first p-type organic semiconductor doped with the ionic dopant.

15. A solid-state dye solar cell (ssDSC) with a solid-state hole transport material (ssHTM), the ssDSC comprising:
a transparent platform;
a transparent conducting oxide (TCO) overlying the transparent platform;
a sensitized n-type semiconductor overlying the TCO;
a ssHTM overlying the dye-sensitized n-type semiconductor comprising:
a neutral charge first p-type organic semiconductor;
a chemically oxidized first p-type organic semiconductor, with silver(I) containing material dopants; and,
a reduced form of the silver(I) containing material, retained as a functional component in the ssHTM; and,
a metal layer overlying the ssHTM.

16. The ssDSC of claim 15 wherein the silver(I) containing materials are selected from a group consisting of silver acetate, silver acetoacetate, silver acetylacetonate, silver bromide, silver carbonate, silver chloride, silver fluoride, silver hexafluoroarsenate, silver hexafluorophosphate, silver iodide, silver nitrate, silver phosphate, silver sulfate, silver tetrafluoroborate, silver trifluoroacetate, silver trifluoromethanesulfonate, silver salts of organic carboxylic acids (carboxylate salts), silver salts of organic phosphonic acids (phosphonate salts), silver salts of organic sulfonic acids (sulfonate salts), silver salts of bis(alkylsulfonyl)imides, silver salts of bis(trifluoroalkylsulfonyl)imides, silver(I) molecular complexes, and combinations of the above-mentioned materials.

17. The ssDSC of claim 15 wherein the silver(I) containing material is silver bis(trifluoromethanesulfonyl)imide (AgTFSI).

18. The ssDSC of claim 15 wherein the first p-type organic semiconductor is selected from a group consisting of molecular (collection of discrete molecules, chemically identical or different), oligomeric, polymeric materials, and combinations thereof.

19. The ssDSC of claim 15 wherein the first p-type organic semiconductor is 2,2′,7,7′-tetrakis(N,N-di-p-methoxyphenylamine)-9,9′-spirobifluorene (Spiro-OMeTAD).

20. The ssDSC of claim 15 wherein the first p-type organic semiconductor has a structure selected from a group consisting of amorphous, crystalline, semi-crystalline, and combinations thereof.

21. The ssDSC of claim 15 wherein the ssHTM further comprises a first p-type organic semiconductor doped with an ionic dopant selected from a group consisting of lithium (Li⁺), sodium (Na⁺), and potassium (K⁺).

22. The ssDSC of claim 15 wherein the sensitized n-type semiconductor is selected from a group consisting of titanium oxide (TiO₂), aluminum oxide (Al₂O₃), tin oxide (SnO₂), magnesium oxide (MgO), tungsten oxide (WO₃), niobium oxide (Nb₂O₅), zinc oxide (ZnO), combinations of the above-mentioned oxides, and doped variations of the above-mentioned oxides.

23. The ssDSC of claim 15 wherein the sensitized n-type semiconductor has a form selected from a group consisting of nanoparticles, nanotubes, nanorods, nanowires, and combinations of the above-mentioned morphologies.

24. The ssDSC of claim 15 wherein the sensitized n-type semiconductor has a thickness in a range of 0.1 to 20 microns.

25. The ssDSC of claim 15 wherein the sensitized n-type semiconductor includes a sensitizer selected from a group consisting of molecular (organic) materials, metal-organic complexes, ruthenium-pyridyl complexes, porphyrins, metalloporphyrins, phthalocyanines, metallophthalocyanines, squaraines, indolenes, coumarins, thiophene and fluorene-based materials, monomeric oligomeric, polymeric photosensitizers, quantum dots, inorganic materials, organic-inorganic materials, and combinations of the above-mentioned materials.

26. The ssDSC of claim 15 further comprising:
a blocking layer interposed between the TCO and the dye-sensitized n-type semiconductor.

27. The ssDSC of claim 15 wherein the percentage of chemically oxidized first p-type organic semiconductor to neutral charge first p-type organic semiconductor is in a range of 0.1 to 25%.
